(19) United States
(12) Patent Application Publication
(10) Pub. No.: US 2010/0012914 A1
(43) Pub. Date: Jan. 21, 2010

(54) CARBON-BASED RESISTIVITY-SWITCHING MATERIALS AND METHODS OF FORMING THE SAME

(75) Inventors: Huiwen Xu, Sunnyvale, CA (US); Er-Xuan Ping, Fremont, CA (US); Andy Fu, San Ramon, CA (US)

Correspondence Address: DUGAN & DUGAN, PC, 245 Saw Mill River Road, Suite 309, Hawthorne, NY, 10532, US

(73) Assignee: SanDisk 3D LLC, Milpitas, CA (US)

(21) Appl. No.: 12/505,122

(22) Filed: Jul. 17, 2009

Related U.S. Application Data
(60) Provisional application No. 61/082,180, filed on Jul. 18, 2008.

(51) Int. Cl. H01L 47/00; H01L 21/00

(52) U.S. Cl. 257/2; 438/482; 257/E47.001; 257/E21.001

(57) ABSTRACT

Methods of forming memory devices, and memory devices formed in accordance with such methods, are provided, the methods including forming a via above a first conductive layer, forming a nonconformal carbon-based resistivity-switchable material layer in the via and coupled to the first conductive layer; and forming a second conductive layer in the via, above and coupled to the nonconformal carbon-based resistivity-switchable material layer. Numerous other aspects are provided.

### CROSS REFERENCE TO RELATED APPLICATIONS

The present application claims the benefit of U.S. Provisional Patent Application Ser. No. 61/082,180, filed Jul. 18, 2008, and titled “Carbon-Based Resistivity-Switching Materials And Methods Of Forming The Same” (“the '180 application”) (Docket No. MXA-325P), which hereby is incorporated by reference herein in its entirety for all purposes.

The present application is related to U.S. patent application Ser. No. 12/421,405, filed Apr. 9, 2009, and titled “Damascene Integration Methods For Graphitic Films In Three-Dimensional Memories And Memories Formed Therefrom” (“the '405 application”) (Docket No. MXD-247), which hereby is incorporated by reference herein in its entirety for all purposes.

The present application also is related to U.S. patent application Ser. No. 12/465,315, filed May 13, 2009, and titled “Carbon-Based Interface Layer For A Memory Device And Methods Of Forming The Same” (“the '315 application”) (Docket No. MXA-293), which hereby is incorporated by reference herein in its entirety for all purposes.

The present application further is related to U.S. patent application Ser. No. 12/499,467, filed Jul. 8, 2009, and titled “Carbon-Based Resistivity-Switching Materials And Methods Of Forming The Same” (“the '467 application”) (Docket No. MXA-294), which hereby is incorporated by reference herein in its entirety for all purposes.

### TECHNICAL FIELD

The present invention relates to microelectronic structures, such as non-volatile memories, and more particularly to carbon-based resistivity-switching materials, such as for use in such memories, and methods of forming the same.

### BACKGROUND

Non-volatile memories formed from reversible resistance-switchable elements are known. For example, U.S. patent application Ser. No. 11/125,939, filed May 9, 2005 and titled “Rewriteable Memory Cell Comprising A Diode And A Resistance-Switching Material” (Docket No. MA-146), which is hereby incorporated by reference herein in its entirety for all purposes, describes a three-dimensional, rewriteable non-volatile memory cell that includes a diode coupled in series with a reversible resistivity-switchable material such as a metal oxide or metal nitride.

It is also known that certain carbon-based films may exhibit reversible resistivity-switching properties, making such films candidates for integration within a three-dimensional memory array. For example, U.S. patent application Ser. No. 11/968,154, filed Dec. 31, 2007, titled “Memory Cell That Employs A Selectively Fabricated Carbon Nano-Tube Reversible Resistance-Switching Element And Methods Of Forming The Same” (Docket No. MXA-241) (hereinafter “the '154 Application”), which is hereby incorporated by reference herein in its entirety for all purposes, describes a rewriteable non-volatile memory cell that includes a diode coupled in series with a carbon-based reversible resistivity-switchable material such as carbon.

However, integrating carbon-based resistivity-switchable materials in memory devices is difficult, and improved methods of forming memory devices that employ carbon-based reversible resistivity-switchable materials are desirable.

### SUMMARY

In a first aspect of the invention, a method of forming a microelectronic structure is provided, wherein the method includes (1) forming a via above a first conductive layer; (2) forming a nonconformal carbon-based resistivity-switchable material layer in the via and coupled to the first conductive layer; and (3) forming a second conductive layer in the via, above and coupled to the nonconformal carbon-based resistivity-switchable material layer.

In a second aspect of the invention, a microelectronic structure is provided that includes (1) a via formed above a first conductive layer; (2) a nonconformal carbon-based resistivity-switchable material layer disposed in the via and coupled to the first conductive layer; and (3) a second conductive layer in the via, above and coupled to the nonconformal carbon-based resistivity-switchable material layer.

In a third aspect of the invention, a memory device is provided that includes (1) a steering element, and (2) a memory element coupled to the steering element, wherein the memory element includes a nonconformal carbon-based resistivity-switchable material layer disposed in a via above a first conductive layer.

Other features and aspects of this invention will become more fully apparent from the following detailed description, the appended claims and the accompanying drawings.

### BRIEF DESCRIPTION OF THE DRAWINGS

Features of the present invention can be more clearly understood from the following detailed description considered in conjunction with the following drawings, in which the same reference numerals denote the same elements throughout.

FIGS. 1A and 1B are cross-sectional, side elevational views of exemplary carbon-based structures formed in accordance with exemplary methods of this invention.

FIGS. 2-5D are cross-sectional, side elevational views of intermediate stages of exemplary embodiments of carbon-based structures formed in accordance with exemplary methods of this invention.

FIGS. 6A and 6B are cross-sectional, side elevational views of further exemplary carbon-based structures formed in accordance with exemplary methods of this invention.

FIGS. 7-12D are cross-sectional, side elevational views of intermediate stages of further exemplary embodiments of carbon-based structures formed in accordance with exemplary methods of this invention.

FIGS. 13-14 are cross-sectional, side elevational views of intermediate stages of additional exemplary embodiments of damascene structures provided in accordance with this invention.

FIG. 15 is a perspective view of an exemplary memory level of a monolithic three dimensional memory array provided in accordance with this invention.

It is to be noted, however, that the appended drawings illustrate only exemplary embodiments of this invention. The drawings are not necessarily drawn to scale. The embodiments shown and described are not intended to limit the scope of the invention, which is defined by the appended claims, for the invention may admit to other equally effective embodiments.

### DETAILED DESCRIPTION

Certain carbon-based films, including but not limited to carbon nanotubes (“CNTs”), graphene, amorphous carbon containing microcrystalline graphitic carbon, amorphous diamond like carbon, etc., may exhibit resistivity switching properties that may be used to form microelectronic non-volatile memories. Such films therefore are candidates for integration within a three-dimensional memory array.

For example, a metal-insulator-metal (“MIM”) stack formed from a carbon-based material sandwiched between two metal or otherwise conducting layers may serve as a resistance change material for a memory cell, e.g., a resistivity-switchable layer. In an MIM memory structure, each “M” represents a metal electrode, and the “I” represents an insulator-type layer used to store a data state. Moreover, a carbon-based MIM stack may be integrated in series with a diode or transistor to create a resistivity-switchable memory device as described, for example, in the '154 Application.

However, conventional “subtractive” integration of carbon-based materials in an MIM may result in damage to the carbon-based material during post-integration processing. For example, subtractive integration may expose the carbon-based material to etching, ashing, and/or wet cleaning processes that may undercut the carbon-based material. Similarly, deposition of gap fill material around the etch-patterned carbon-based material may expose the carbon-based material to detrimental oxygen and/or nitrogen plasma processing. Gap fill deposition also may require planarization, which further may expose the carbon-based material to harmful shearing forces.

To avoid such detrimental effects, methods in accordance with this invention use damascene integration techniques to form a layer of carbon-based resistivity-switchable material in an MIM stack. In exemplary embodiments of this invention, a MIM is formed by forming a via above a first conductive layer, forming a nonconformal carbon-based resistivity-switchable material layer in the via and coupled to the first conductive layer, and forming a second conductive layer in the via, above and coupled to the nonconformal carbon-based resistivity-switchable material layer. In some exemplary embodiments, the MIM may be integrated in series with a steering element, such as a diode, to form a memory cell.

Methods and devices in accordance with this invention may be used with any resistivity-switchable material that can be deposited in a nonconformal manner, although the benefits of the invention may vary depending on the selection and relative sensitivity of the resistivity-switchable material. For instance, in addition to carbon-based films mentioned above, other resistivity-switchable materials that may be nonconformally deposited include many metal oxides and metal nitrides that are known to exhibit resistivity-switching capabilities.

For simplicity, however, the remaining discussion refers to carbon-based resistivity-switchable materials. In addition, for simplicity, non-conformally deposited carbon-based resistivity-switchable material will be referred to herein as “nonconformal carbon-based resistivity-switchable material.”

### Damascene Integration Schemes

As described further in more detail below, exemplary methods in accordance with this invention form microelectronic structures, such as memory cells, using damascene integration techniques and non-conformal formation of carbon-based resistivity-switchable material. Such techniques may reduce damage to the resistivity-switchable materials that may otherwise occur in subsequent processing steps. In some exemplary embodiments, a metal adhesion layer and/or a top electrode may be conformally deposited on the nonconformal carbon-based resistivity-switchable material. Such adhesion/top electrode layers may protect the nonconformal carbon-based resistivity-switchable material from damage caused by subsequent processing steps, such as etch/clean processes.

As used herein, conformal formation refers to isotropic, nondirectional formation, wherein for example, a deposited layer conforms to the horizontal as well as vertical topography of an underlying layer. An example of conformal formation includes deposition of a material on bottom and sidewalls of a target layer. By contrast, nonconformal formation refers to anisotropic, directional formation, wherein, for example, a deposited layer conforms primarily to only the horizontal topography, preferably without depositing material on the vertical surfaces, such as sidewalls.

In accordance with this invention, damascene integration techniques are used to form a layer of nonconformal carbon-based resistivity-switchable material. Such integration techniques facilitate covering the nonconformal carbon material with a conductive layer, for instance a metal layer, without an intervening processing step. The conductive layer covering the nonconformal carbon material may shield the nonconformal carbon material from detrimental effects of subsequent processing steps. Avoiding such intervening processing steps may reduce the overall number of processing steps, and avoid direct exposure of the nonconformal carbon material to additional processing, such as etching, ashing and wet clean processes, thereby reducing the potential for damage to the nonconformal carbon material.

Compared to conformal formation in damascene integration, nonconformal formation of a resistivity-switchable material in damascene integration may eliminate a post-integration gap-fill step. Post-integration gap-fill deposition in situations involving small-geometry and/or high-aspect-ratio vias often requires use of a high density plasma, followed by planarization. Use of a high density plasma may result in oxygen or amine radicals that likely would react with, and be detrimental to, the resistivity-switchable material, especially carbon-based materials.

Further, resistivity-switchable materials, such as amorphous carbon (“aC”), may be damaged by interaction with other elements and compounds associated with post-integration processing, such as chemical mechanical planarization (“CMP”). Nonconformal formation of the resistivity-switchable material may eliminate a CMP step after a gap fill step. Shearing forces during CMP can be detrimental to resistivity-switchable films, including carbon-based material films. Shielding of the resistivity-switchable film provides support the resistivity-switchable film during CMP.

In the event of a conformal formation of resistivity-switchable material, using CMP may open, e.g., expose, the resistivity-switchable material deposited on the sidewall to CMP slurry. Exposure of resistivity-switchable material, especially carbon-based material, may result in moisture adsorption, defect contamination, and an electrical short of the resistivity-switchable element. Likewise, a wet clean may result in disadvantageous moisture adsorption by a carbon-based film, which tends to absorb moisture due to possible CH content in the film, so reducing the exposure of the film during a wet clean may reduce the moisture adsorption.

Shielding of the resistivity-switchable element also may reduce the potential for damage caused by plasma and interaction between reactive radicals and the resistivity-switchable memory material during plasma-enhanced chemical vapor deposition (“PECVD”) or high density plasma chemical vapor deposition (“HDPCVD”) gap fill deposition. Oxygen (“O”) and amine (“NH₂”) radicals generated during high density plasma (used in oxide or nitride deposition) can damage resistivity-switchable materials, such as carbon-based materials, so damascene-formed MIM integration may reduce damage arising during the gap fill deposition.

In addition to non-conformal deposition of read writable material, selective formation of resistivity-switchable material can serve the same purpose. Selective formation of resistivity-switchable material may result in formation of resistivity-switchable material on a bottom metal conductor, but not on the surrounding dielectric material. For example, PECVD-style growth of CNTs often involves using a metal catalyst, so PECVD-style growth of CNTs may be designed to form CNTs only on a metal electrode at a bottom of a damascene hole but not on a dielectric oxide of a damascene side wall or top. Similarly, metal oxide formed by oxidation of a metal electrode may be designed to only occur on a metal electrode at the bottom of the damascene hole.

In addition, nonconformal formation of the resistivity-switchable material may allow for better control and uniformity of layer formation in the context of small geometries. As the geometry becomes smaller, the capability of conformal deposition to deposit a controllable and uniform sidewall thickness diminishes. Likewise, nonconformal formation of the resistivity-switchable material may result in less material on the sidewall of a damascene via or other feature. In contrast, conformal damascene integration of both the resistivity-switchable material and the top electrode would result in more material on the sidewall. When feature size geometry is reduced, the extra sidewall material may exceed the size of the damascene via, in which case conformal damascene sidewall integration may not work.

Whereas exemplary embodiments of the invention use nonconformal deposition of the resistivity-switchable material to form a layer of resistivity-switchable material that can be covered by a conductive layer (e.g., titanium nitride, tungsten nitride, or another adhesion and diffusion barrier layer, another conductive layer, etc.), other embodiments may use etch back of the resistivity-switchable material to form a layer of resistivity-switchable material that may be covered by a conductive layer, in the event that the etch back does not render the resistivity-switchable material inoperable as a memory element.

MIM Without a Diode

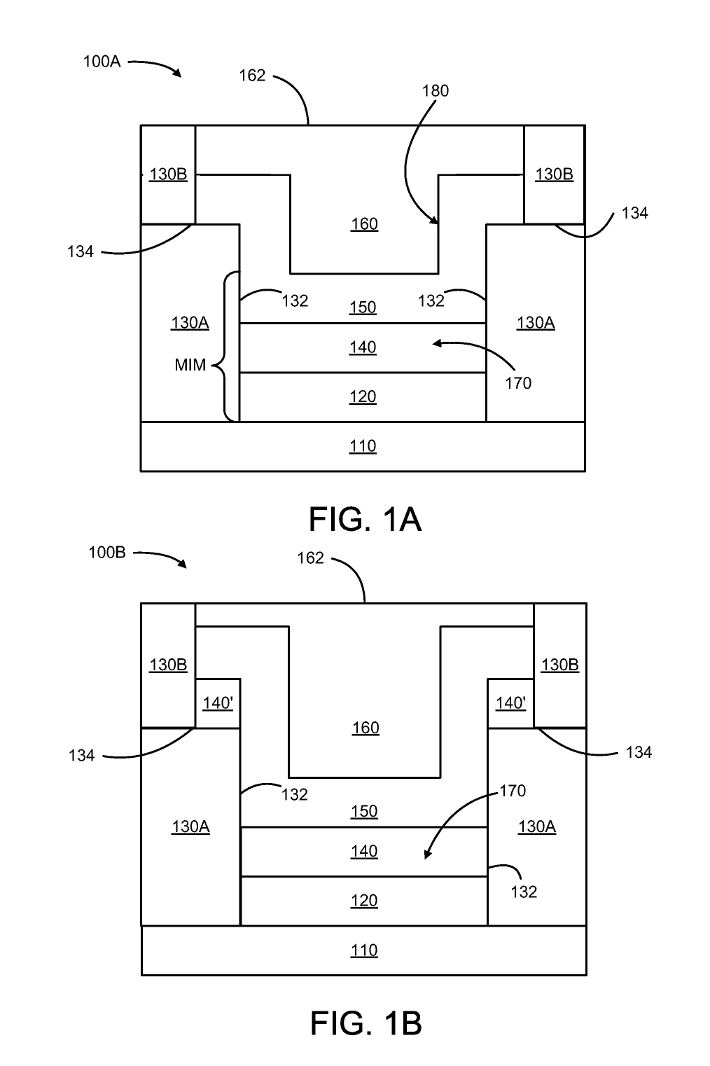

Referring to FIGS. 1A and 1B, cross-sectional side elevational views of exemplary microelectronic structures 100A and 100B in accordance with this invention are now described. Microelectronic structures 100A and 100B each include a MIM structure without a diode. A steering element, such as a CMOS transistor, optionally is located elsewhere on the device, such as built into the substrate. Such an integration scheme is especially applicable to resistivity-switchable memory materials formed using directional deposition with little sidewall coverage (˜0% conformality).

As shown in FIGS. 1A and 1B, microelectronic structures 100A and 100B may include a bottom conductor 110. The bottom conductor 110 may comprise, for instance, tungsten, copper, aluminum, or another similar conductive material. The bottom conductor 110 may range from about 500 to 3000 angstroms, more preferably about 1200-2000 for tungsten. Other materials and/or thicknesses may be used.

The bottom conductor 110 may be one of a plurality of rail conductors that have been patterned and etched from a conductive layer, then isolated by dielectric gap fill and planarized, in accordance with conventional techniques. For instance, a rail conductor photomask may be used to pattern the bottom conductors, which may have a critical dimension (“CD”) wider than that of features to be formed above the rail conductor, to compensate for potential misalignment of the features and the rail. A corresponding top conductor substantially perpendicular to the bottom rail conductor 110 later may be patterned from another conductive layer using a similar rail conductor photomask.

On the bottom conductor 110 are depicted a bottom barrier layer 120, and a dielectric gap fill layer 130A. The bottom barrier layer 120 is a conductive layer in ohmic contact with the bottom conductor 110, which also is a conductive layer. The bottom barrier layer 120, acting as a lower metal electrode in a MIM structure, may comprise tungsten nitride (“WN”), titanium nitride, molybdenum (“Mo”), tantalum nitride (“TaN”), or tantalum carbon nitride (“TaCN”) or another similar conductive adhesion or barrier material. Exemplary thicknesses for the bottom barrier layer 120 range from about 20 to 3000 angstroms, more preferably about 100 to 1200 angstroms for TiN. The bottom conductor 110 and/or bottom barrier layer 120 form a first conductive layer of microelectronic structures 100A and 100B.

The dielectric gap fill layer 130A may comprise a dielectric material, such as silicon dioxide (“SiO₂”), or other similar dielectric material commonly used in semiconductor manufacturing. For example, dielectric gap fill layer 130A may include from about 2000-7000 angstroms of silicon dioxide, although other thicknesses and dielectric materials may be used. Dielectric gap fill layer 130A includes a via 170. For example, as described in more detail below, via 170 may be formed in dielectric gap fill layer 130A using damascene integration techniques, as are known in the art.

As depicted, the nonconformal carbon-based resistivity-switchable material layer 140 is formed in via 170 and deposited onto the bottom barrier layer 120. The nonconformal carbon-based resistivity-switchable material layer 140 may be characterized as a resistivity-switchable element that may exhibit resistance-switching capabilities by which the data state of the memory cell may be stored. The nonconformal carbon-based resistivity-switchable material layer 140 may comprise amorphous carbon, graphene, carbon nanotubes, or other similar carbon-based resistivity switchable material. The nonconformal carbon-based resistivity-switchable material layer 140 may have a thickness ranging from about 10 to 5000 angstroms, more preferably about 50 to 1000 angstroms for amorphous carbon.

Numerous techniques may be used to form nonconformal resistivity-switchable materials. As in FIG. 1A, the resistivity-switchable material may be selectively grown on a layer within via 170. In other instances, as in FIG. 1B, nonconformal deposition may be achieved using, for instance, chemical vapor deposition (“CVD”), such as PECVD, physical vapor deposition (“PVD”), ion implantation, or other similar process. In some embodiments, nonconformal resistivity-switchable material may be produced using a combination of temperature, pressure, and ionic species reduction.

In one or more embodiments of the invention, a PECVD process is provided that may form graphene, graphitic carbon, carbon nanotubes, amorphous carbon with microcrystalline graphitic carbon, amorphous diamond like carbon (“DLC”), and other carbon-based resistivity-switchable materials. As is described further in the '467 application, such a PECVD process may provide numerous advantages over conventional thermal chemical vapor deposition processes including, in some embodiments, (1) reduced thermal budget; (2) broad process windows; (3) adjustable programming voltages and currents; and (4) tailored interfaces.

For instance, Table 1 below provides details of an exemplary embodiment of the present invention, which describe an exemplary process window to produce nonconformal amorphous-carbon-based resistivity-switchable material using PECVD. The nonconformal carbon-based resistivity-switchable material may comprise nanometer-sized or larger regions of crystalline graphene (referred to herein as “graphitic nanocrystallites”).

In particular embodiments, a nonconformal carbon-based resistivity-switchable material may be formed using hydrocarbon compounds CₓH_{y} at a flow rate of about 50-100 sccm, Helium at a flow rate of 50-20,000 sccm, and more narrowly of about 1000-3000 sccm, an RF power of about 30-250 Watts, a chamber pressure of about 2.5-7 Torr and an electrode spacing of about 200-500 mils. The resultant carbon resistivity-switchable film produced by the above example was conductive (e.g., p equals about 50,000 Ω/□ for about 1000 Angstroms) with nanocrystallites of about 2-5 nanometers.

TABLE 1
PARAMETERS FOR EXEMPLARY PECVD OF
NONCONFORMAL aC RESISTIVITY-SWITCHABLE MATERIAL

| PROCESS PARAMETER | BROAD RANGE | NARROW RANGE |
|---|---|---|
| Precursor C_{X}H_{Y} | x = 2-4; y = 2-10 | C_{X}H_{Y} in which |
| | | double or single |
| | | bond CC is |
| | | dominant |
| Carrier Gas | He, Ar, H₂, Kr, | He, H₂ |
| | Xe, N₂ etc. | |
| Carrier/Precursor Ratio | 1:1-100:1 | 10:1-50:1 |
| Chamber Pressure (Torr) | 1-10 | 2.5-7 |
| 1st RF Power (Watts) | 30-1000 | 30-250 |
| (at 10-30 MHz) | | |
| 2nd RF Power (Watts) | 0-500 | 0-100 |
| (at 90-500 KHz) | | |
| RF Power Density (W/in²) | 0.10-20 | 0.30-5 |
| Process Temperature (° C.) | 300-650 | 300-550 |
| Electrode Spacing (Mils) | 200-1000 | 200-500 |
| Deposition Rate (Å/sec) | ≦33 | ≦3 |

The process parameters of Table 1 may be used to perform directional nonconformal deposition of aC. For instance, increasing an ionic component (e.g., carrier gas species) of a plasma compared to a precursor component (e.g., carbon species) of the plasma may provide a flux of ionic species that carry precursor species to a substrate surface with increased directionality, resulting in surface reactions activated by physical bombardment. Use of high and/or low frequency RF may assist in driving the ionic species (and thus precursor species) to the substrate surface, as may substrate bias.

Similarly, Table 2 below provides broad and narrow process windows for directional gapfill of carbon material by PECVD. Preferably, precursor gases predominantly contain carbon-carbon single bonds (“C—C”) or double bonds (“C═C”).

TABLE 2
EXEMPLARY PECVD PROCESS PARAMETERS OF
DIRECTIONAL GAPFILL CARBON MATERIAL

| PROCESS PARAMETER | BROAD RANGE | NARROW RANGE |
|---|---|---|
| Carrier/Precursor Ratio | 2:1 < x < 100:1 | 40:1 < X < 60:1 |
| Chamber Pressure (Torr) | 2-8 | 4-7 |
| 1^{st} RF frequency (Mhz) | 10-50 | 12-15 |
| 2^{nd} RF frequency (Khz) | 90-500 | 90-250 |
| 1^{st} RF power density (W/in²) | 1.3-17 | 1.9-3 |
| 2^{nd} RF/1^{st} RF density ratio | 0-1 | 0.4-0.6 |
| Process Temperature (° C.) | 200-650 | 500-600 |

By comparison, Table 3 below describes an exemplary, broad parameter set and an exemplary, narrow process window for forming material containing nanocrystalline graphitic carbon (“GC”) within a PECVD chamber using a processing gas comprising one or more hydrocarbon compounds and a carrier/dilutant gas. The nanocrystalline graphitic carbon-containing material may be used to form a C-based switching layer. As in Table 1, the precursor hydrocarbon compounds may have the formula CₓH_{y}, with x ranging from about 2 to 4 and y ranging from about 2 to 10, and the carrier gas may comprise an inert or non-reactive gas such as one or more of He, Ar, H₂, Kr, Xe, N₂, or other similar gas.

TABLE 3
EXEMPLARY PECVD PROCESS PARAMETERS FOR GC

| PROCESS PARAMETER | BROAD RANGE | NARROW RANGE |
|---|---|---|
| Precursor Flow Rate (sccm) | 50-5000 | 50-100 |
| Carrier/Precursor Ratio | >1:1 | 5:1 ≦ x ≦ 50:1 |
| Chamber Pressure (Torr) | 0.2-10 | 4-6 |
| 1^{st} RF frequency (Mhz) | 10-50 | 12-17 |
| 2^{nd} RF frequency (Khz) | 90-500 | 90-150 |
| 1^{st} RF power density (W/cm²) | 0.12-2.80 | 0.19-0.50 |
| 2^{nd} RF power density (W/cm²) | 0-2.8 | 0-0.5 |
| Process Temperature (° C.) | 450-650 | 550-650 |
| Heater to Showerhead (Mils) | 300-600 | 325-375 |

Referring again to FIGS. 1A and 1B, a top barrier layer 150 may be formed in via 170 and above the nonconformal carbon-based resistivity-switchable material layer 140. In some embodiments, top barrier layer 150 may extend up sidewalls 132 of gap fill layer 130A. Via 170 may have a depth from about 500 to 3000 angstroms (without a diode). Other via depths may be used. As with the bottom barrier layer 120, the top barrier layer 150, acting as an upper metal electrode in the MIM structure, may comprise similar conductive adhesion or barrier materials. Exemplary thicknesses for the top barrier layer 150 range from about 20 to 3000 angstroms, more preferably about 100 to 1200 angstroms for TiN.

Above the top barrier layer 150, and within a volume of a cavity 180 formed in top barrier layer 150 is a top conductor 160. The top barrier layer 150 is a conductive layer in ohmic contact with the top conductor 160. The top barrier layer 150 and/or the top conductor 160 form a second conductive layer of microelectronic structures 100A and 100B. The top conductor 160 may comprise tungsten, copper, aluminum, or another similar conductive material. The top conductor 160 may range from about 500 to 3000 angstroms, more preferably about 1200-2000 for tungsten. Other materials and/or thicknesses may be used. Also, layers of the MIM stack may form good adhesion by potentially alloying.

In some embodiments of this invention, bottom barrier layer 120 and/or top barrier layer 150 optionally may be omitted (not shown), such that the bottom conductor 110 and/or the top conductor 160 is formed in direct contact with the nonconformal carbon-based resistivity-switchable material 140. The determination of whether to include bottom barrier layer 120 and/or top barrier layer 150 largely depends on the choice of materials for the nonconformal carbon-based resistivity-switchable material 140 and the bottom conductor 110 and/or the top conductor 160. In the case of tungsten (“W”) as the material of choice for the bottom conductor 110 and/or the top conductor 160, an exemplary embodiment of the present invention may involve use of titanium nitride (“TiN”) as the bottom barrier layer 120 and/or the top barrier layer 150. In particular, such barrier layers may be useful to increase adhesion between the W conductors and the nonconformal carbon-based resistivity-switchable material 140. The same principles also apply to the other figures.

Moreover, the choice of bottom electrode materials, e.g., bottom conductor 110 and bottom barrier layer 120, may be used to modulate the crystallite orientation of the resistivity-switchable layer 140. For example, using heavily doped silicon (“Si”) in place of a W bottom conductor 110 and a TiN bottom barrier layer 120 may generate a random crystallite orientation for the resistivity-switchable layer 140, while forming the resistivity-switchable layer 140 on TiN or W may generate crystallites within the nonconformal carbon-based resistivity-switchable material 140 with basal planes normal to the interface. Furthermore, formation of the top electrode may be simplified down to a metal gap fill of W, copper (“Cu”), or aluminum (“Al”), or other similar conductive material.

Thus, as depicted in FIGS. 1A and 1B, microelectronic structures 100A and 100B each include a first conductive layer (e.g., bottom conductor 110 and/or bottom barrier layer 120), a via 170 formed above the first conductive layer, a nonconformal carbon-based resistivity-switchable material layer 140 disposed in the via 170 and coupled to the first conductive layer, and a second conductive layer (e.g., top barrier layer 150 and/or the top conductor 160) in the via 170, above and coupled to the nonconformal carbon-based resistivity-switchable material layer 140.

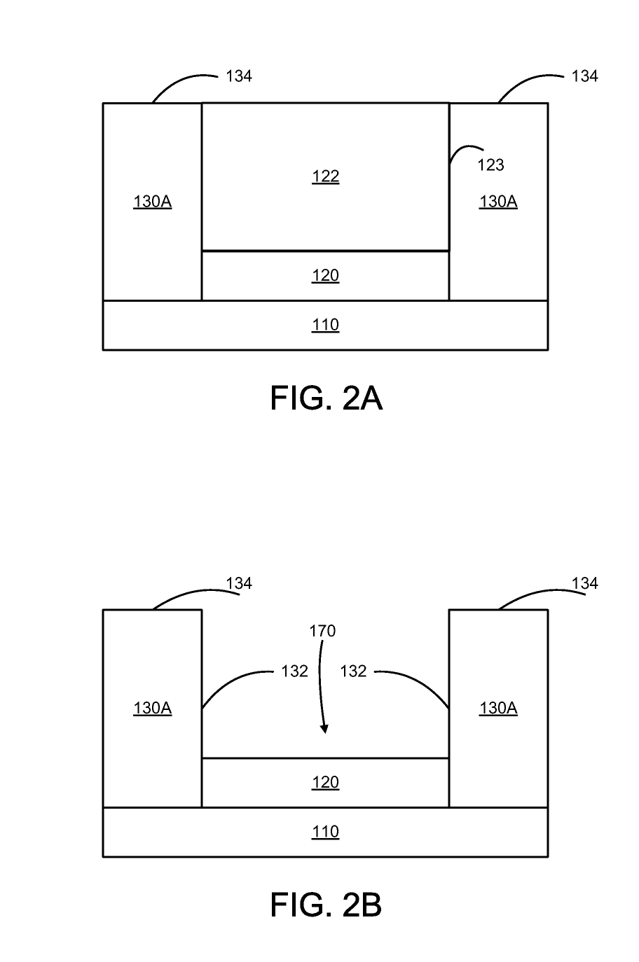

Referring to FIGS. 2A to 4B, cross-sectional side elevational views of intermediate stages of exemplary device fabrication methods of this invention. Intermediate products of some, but not all process steps are depicted, and the progression of one intermediate product to the next is explained in the following text, taking into account the ordinary level of skill in the semiconductor manufacturing arts.

As shown in FIGS. 2A and 2B, formation of exemplary microelectronic structures 100A and 100B begins with formation of the bottom conductor 110, followed by formation barrier layer 120. In one exemplary embodiment, the bottom barrier layer 120 and sacrificial material 122 may be deposited onto conductor 110, which are then etched to form a pillar 123, followed by deposition and etch back of gap fill 130A. Sacrificial material 122 is depicted in FIG. 2B as having been removed to form via 170. Alternatively, etching of barrier layer 120 may be followed by deposition and etch back of gap fill 130A to form via 170, selectively etching the dielectric material 130A to stop the etch upon reaching the bottom barrier layer 120. In another embodiment, gap fill 130A may be deposited and etched back to form via 170, into which bottom barrier layer 120 may be (nonconformally) deposited, possibly followed by CMP.

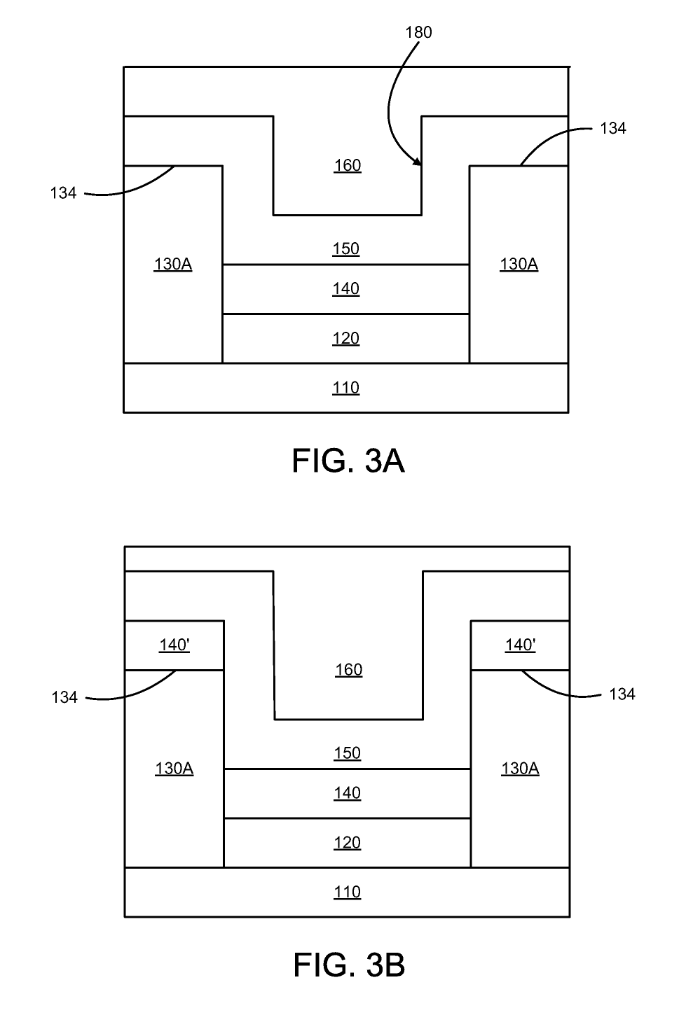

As shown in FIGS. 3A and 3B, a layer 140 of nonconformal carbon-based resistivity-switchable material, such as amorphous carbon, is deposited in via 170 and coupled to bottom barrier layer 120. For instance, increasing an ionic component (e.g., carrier gas species) of a plasma compared to a precursor component (e.g., carbon species) of the plasma may provide a flux of ionic species that carry precursor species to a substrate surface with increased directionality. Use of high and/or low frequency RF may assist in driving the ionic species (and thus precursor species) to the substrate surface, as may substrate bias.

In the embodiment of FIG. 3A, a carbon layer may be deposited selectively onto the metal layer 120 using selective deposition techniques set forth in related, co-owned application, U.S. patent application Ser. No. 12/466,197, filed May 14, 2009, titled “CARBON NANO-FILM REVERSIBLE RESISTANCE-SWITCHABLE ELEMENTS AND METHODS OF FORMING THE SAME,” to Li et al. (“the '197 application”) (SD-MXA-291), herein incorporated by reference in its entirety for all purposes. Use of selective deposition may involve omission of the bottom barrier layer 120, so that the nonconformal carbon-based resistivity-switchable material layer 140 is deposited directly on bottom conductor 110.

Selective deposition of the nonconformal carbon-based resistivity-switchable material layer 140 may be followed by deposition of metal barrier material, for the top barrier layer 150, in the via 170, with some metal barrier material being deposited above the gap fill material 130A. In the illustrated embodiment, barrier layer 150 is a conductive layer formed on nonconformal carbon-based resistivity-switchable material layer 140. The conductive layer is disposed on a virgin layer of the resistivity-switchable material, insofar as the nonconformal carbon-based resistivity-switchable material layer 140 has not undergone an intervening processing step capable of damaging the resistivity-switchable material.

Conformal deposition of barrier layer 150 will cause the barrier layer 150 to form up along the sidewalls 132 of gap fill layer 130A, forming a cavity 180 lined with barrier material in via 170. In some embodiments (not shown), non-conformal deposition of barrier layer 150 may be used. In such instances, the non-conformal barrier layer 150 preferably covers substantially all of the nonconformal resistivity-switchable material layer 140. Above the barrier material for the top barrier layer 150, and into cavity 180, a layer of conductive material may be formed, out of which the top conductor 160 would be formed.

In another exemplary embodiment, as shown in FIG. 3B, nonconformal carbon-based resistivity-switchable material layer 140 may be deposited non-selectively on bottom barrier layer 120 in via 170, with some nonconformal carbon-based resistivity-switchable material 140′ being deposited above the gap fill material 130A, followed by deposition of the barrier material for the top barrier layer 150 also in the via 170. Thereafter, the conductive material for the top conductor 160 may be deposited.

The nonconformal carbon-based resistivity-switchable material 140 may include carbon in many forms, including CNTs, graphene, graphite, amorphous carbon, graphitic carbon and/or diamond-like carbon. The nature of the carbon-based layer may be characterized by its ratio of forms of carbon-carbon bonding. Carbon typically bonds to carbon to form either an sp²-bond (a trigonal double C=C bond) or an sp³-bond (a tetrahedral single C—C bond). In each case, a ratio of sp²-bonds to sp³-bonds can be determined via Raman spectroscopy by evaluating the D and G bands. In some embodiments, the range of materials may include those having a ratio such as MᵤN_{z} where M is the sp³ material and N is the sp² material and y and z are any fractional value from zero to 1 as long as y+z=1. Diamond-like carbon comprises mainly sp³-bonded carbon and may form an amorphous layer.

Depending on the carbon-based material used, different formation techniques may be used. For instance, substantially pure carbon nanotubes may be deposited by chemical vapor deposition growth techniques, colloidal spray on techniques, and spin on techniques. Additionally, carbon material deposition methods may include, but are not limited to, sputter deposition from a target, plasma-enhanced chemical vapor deposition, physical vapor deposition, chemical vapor deposition, arc discharge techniques, laser ablation, and other similar techniques. Deposition temperatures may range from about 300° C. to 900° C. A precursor gas source may include, but is not limited to, hexane, cyclo-hexane, acetylene, single and double short chain hydrocarbons (e.g., methane), various benzene based hydrocarbons, polycyclic aromatics, short chain ester, ethers, alcohols, or a combination thereof. In some cases, a “seeding” surface may be used to promote growth at reduced temperatures (e.g., about 1-100 angstroms of iron (“Fe”), nickel (“Ni”), cobalt (“Co”) or the like, although other thicknesses may be used).

In yet another exemplary embodiment, nonconformal carbon-based resistivity-switchable material layer 140 may be deposited on bottom barrier layer 120 in a shorter version of via 170, with some nonconformal carbon-based resistivity-switchable material possibly being deposited above the gap fill material 130A, followed by deposition of the barrier material for the top barrier layer 150 also in the shorter version of via 170. With the barrier material for the top barrier layer 150 in place to cover and protect the nonconformal carbon-based resistivity-switchable material layer 140, an etch back or CMP process might be used to planarize the shorter version of the via 170, making the MIM stack coplanar with the gap fill layer 130A, leaving the nonconformal carbon-based resistivity-switchable material layer 140 covered by the top barrier layer 150. More gap fill dielectric 130A then could be deposited and etched back to the top barrier layer 150 to form an upper portion of via 170, after which the conductive material for the top conductor 160 could be deposited. Deposition of the conductive material for the top conductor 160 may be preceded by deposition of additional barrier material to augment the barrier layer above the nonconformal carbon-based resistivity-switchable material layer 140 as part of the formation of top barrier layer 150.

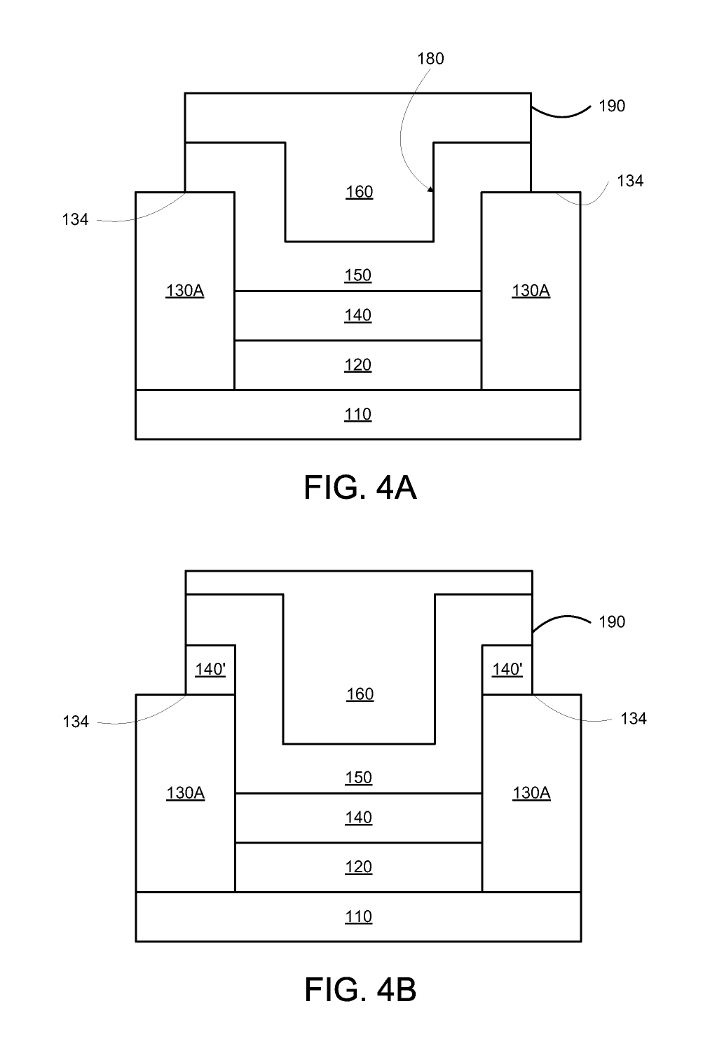

As shown in FIGS. 4A and 4B, the barrier material 150, the conductive material 160, and any nonconformal carbon-based resistivity-switchable material 140′ above the gap fill layer 130A may be patterned and etched back to the gap fill layer 130A, exposing a rail 190 of the top barrier layer 150 and the top conductor 160. The rail 190 may be patterned using a photomask similar to that used to form rail conductor 110, for instance. Additional gap fill dielectric material 130B (see FIG. 1) may then be added to raise the gap fill layer 130A to at least the height of the top conductor 160. Depending on the desired outcome of subsequent processing, the gap fill layer 130B may be planarized, such as by CMP, to make the gap fill layer 130B coplanar with a top surface 162 of the top conductor 160. The result is depicted in FIG. 1. Alternatively, various other processes may be performed, such as the deposition (not shown) of a subsequent bottom barrier layer 120 (for the next level of the device), or excess dielectric material, which may be used, for instance, to create a pad layer at a top level of memory device, or to serve as a dielectric layer 130A of a subsequent device level, into which vias 170 may be etched for further processing.

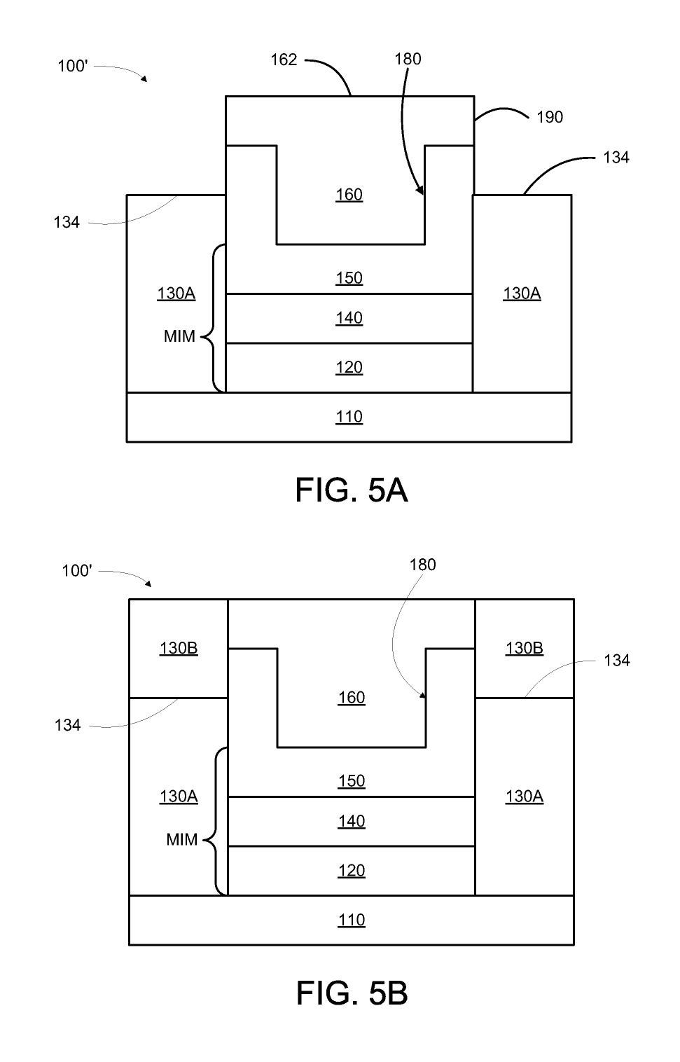

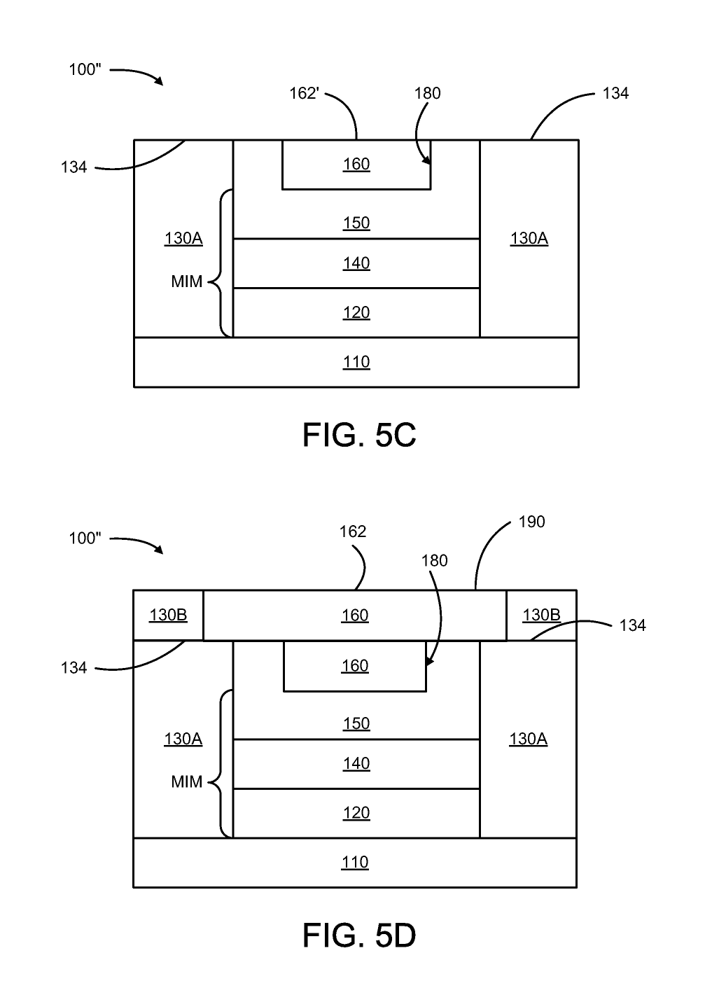

Alternative exemplary embodiments are shown in FIGS. 5A to 5D. In FIGS. 5A and 5B, exemplary microelectronic structure 100′ includes a top conductor rail 190 as having been patterned and etched to have a width similar to that of the pillar features below it, to conserve space. Although the top conductor 160 is shown in FIGS. 5A and 5B as having the same width as the MIM structure below it, practical considerations involving potential misalignment of features often favor having the width of the top conductor 160 greater than the width of the MIM structure, as shown in FIGS. 1A, 1B, 5D, 6A, and 6B. Having conductors 110, 160 wider than the features, e.g., MIM structure, between them affords some margin for misalignment when the features are formed.

In FIGS. 5C and 5D, exemplary microelectronic structure 100″ includes a barrier layer 150 and conductive material 160 above the gap fill layer 130A as having been planarized into surface 162′, such as by CMP, to be co-exposed and made coplanar with a top surface 134 of the gap fill layer 130A. If the top barrier layer 150 extends vertically up the sidewalls of the gap fill layer 130A to the level of the top surface of the gap fill layer 130A, then such planarization will co-expose the top barrier layer 150 and the top conductor 160 along with the gap fill layer 130A. The alternative result 100″ is depicted in FIG. 5C. More conductive material 160 may be deposited on surfaces 162′ and 134, patterned, etched into rail 190, isolated with gap fill 130B, and planarized, as shown in FIG. 5D.

MIM with a Diode

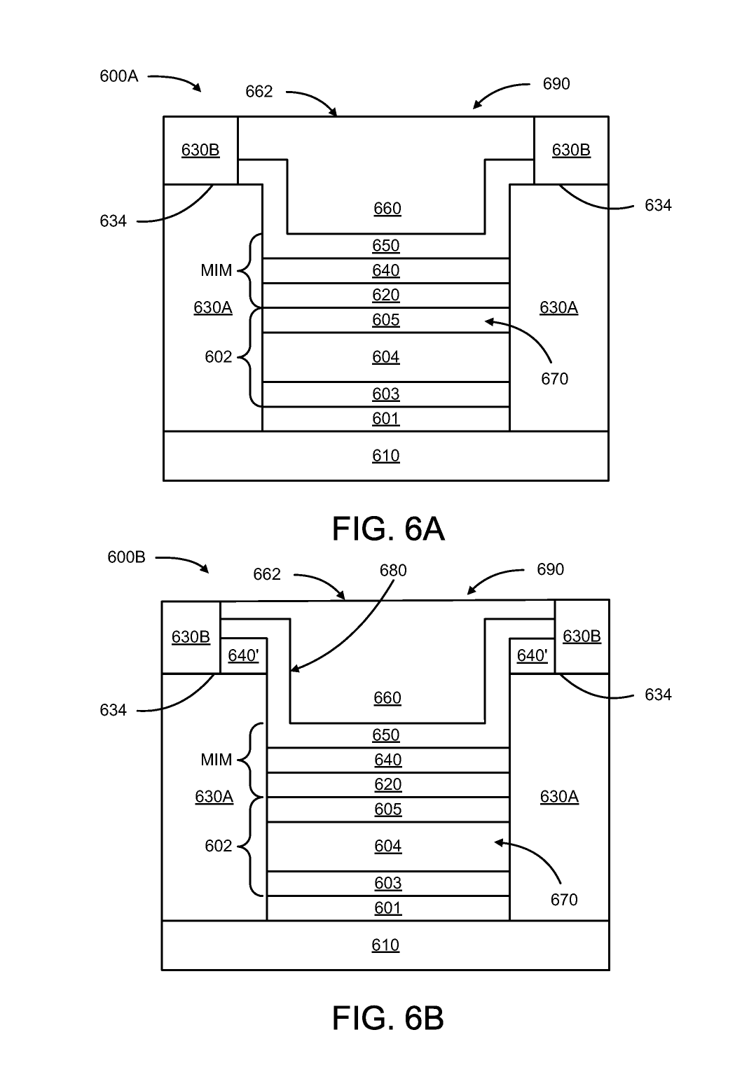

Referring to FIGS. 6A and 6B, cross-sectional, side elevational views depict additional exemplary microelectronic structures 600A and 600B in accordance with the present invention. Microelectronic structures 600A and 600B may share similarities with microelectronic structures 100A and 100B, and layers of microelectronic structures 600A and 600B may comprise materials and thicknesses similar to those of analogous layers in microelectronic structures 100A and 100B. As in FIGS. 1 to 5, the choice of materials is consistent with the description of the present invention as set forth herein.

FIGS. 6A and 6B depict a carbon-based resistivity-switching material memory element incorporated as part of a two terminal memory cell including a selection device or steering element. Microelectronic structures 600A and 600B include an MIM structure with a diode as the steering element. In other exemplary embodiments formed in accordance with the present invention, the memory element may be coupled in series with a thin film transistor, or other similar steering element, to form a memory cell. The diode is formed in substantially vertical alignment with a layer of nonconformal carbon-based resistivity-switchable material. As depicted, the diode is formed below the layer of resistivity-switchable material, but the diode also may be formed above it. Such an integration scheme also is especially applicable to resistivity-switchable memory materials formed using directional deposition with little sidewall coverage (˜0% conformality).

As shown in FIGS. 6A and 6B, microelectronic structures 600A, 600B may include a bottom conductor 610, on which is deposited on an adhesion layer 601, which also may serve as a barrier layer and may include conductive adhesion or barrier material. The bottom conductor 610 may comprise, for instance, 500-3000 angstroms of W, or another similar conductive material. The adhesion layer 601, also acting as a barrier layer, may comprise, for instance, 20-3000 angstroms of WN, TiN, Mo, TaN, or TaCN or another similar conductive adhesion or barrier material. The adhesion layer 601 is a conductive layer in ohmic contact with the bottom conductor 610, which also is a conductive layer. The bottom conductor 610 and/or bottom adhesion layer 601 may form a first conductive layer of microelectronic structures 600A and 600B.

On top of the adhesion layer 601, a pn junction diode 602 may be formed. The layers of the diode 602 may comprise Si, germanium, silicon germanium (“SiGe”), or other similar semiconductor material. A variety of dopants may be used, such as phosphorus for n+ layer 603 and boron for p+ layer 605, or other similar dopants. Furthermore, the diode 602 may comprise a p-i-n, n-p, or n-i-p diode. Exemplary thicknesses of the diode 602 range between 400 and 4000 angstroms, depending on whether an intrinsic region is included.

Diode 602 may formed of a heavily doped semiconductor layer of a first type, such as n+ layer 603, having an exemplary thickness of between 200 and 800 angstroms; followed by an intrinsic or lightly doped semiconductor layer, such as i layer 604, having an exemplary thickness of between 600 and 2400 angstroms, which is followed by a heavily doped semiconductor of a second type, such as p+layer 605, having an exemplary thickness of between 200 and 800 angstroms.

Above the diode 602 is deposited a bottom barrier layer 620. The bottom barrier layer 620, acting as a lower metal electrode in the MIM structure, may comprise, for instance, 20-3000 angstroms of TiN or another similar conductive barrier material.

In some embodiments, an optional silicide region, e.g., titanium silicide (“TiSi₂”) or other similar silicide, may be formed in contact with the diode 602 as barrier layer 620. As described in U.S. Pat. No. 7,176,064, which is hereby incorporated by reference herein in its entirety for all purposes, silicide-forming materials, such as titanium and cobalt, react with deposited silicon during annealing to form a silicide layer. The lattice spacings of titanium silicide and cobalt silicide are close to that of silicon, and it appears that such silicide layers may serve as “crystallization templates” or “seeds” for adjacent deposited silicon as the deposited silicon crystallizes (e.g., the silicide layer enhances the crystalline structure of diode during annealing). Lower resistivity silicon thereby is provided. Similar results may be achieved for silicon-germanium alloy and/or germanium diodes.

In some embodiments using a silicide region to crystallize the diode, the silicide region may be removed after such crystallization, so that the silicon region does not remain in the finished structure. In some embodiments, a Ti-rich barrier layer 620 may react with an aC switchable layer to form titanium carbide (“TiC”), which may improve adhesion with the aC layer.

Surrounding the microelectronic structures 600A and 600B are dielectric gap fill layers 630A, 630B, respectively. The dielectric gap fill layers 630A, 630B may comprise, for instance, 1500-4000 angstroms of a dielectric material, such as silicon nitride (“Si₃N₄”), SiO₂, as is commonly used in semiconductor manufacturing, or other similar dielectric material. Dielectric gap fill layers 630A, 630B each include a via 670. For example, as described in more detail below, via 670 may be formed in dielectric gap fill layer 630A/630B using damascene integration techniques, as are known in the art.

Onto the bottom barrier layer 620 is formed a nonconformal carbon-based resistivity-switchable material layer 640, which may be characterized as a resistivity-switchable element. The resistivity-switchable element may exhibit resistance-switching capabilities by which the data state of the memory cell may be stored. The nonconformal carbon-based resistivity-switchable material layer 640 may comprise, for instance, 10-5000 angstroms of amorphous carbon, graphene, carbon nanotubes, or other similar resistivity-switchable material.

Above the nonconformal carbon-based resistivity-switchable material layer 640 is a top barrier layer 650 that may extend up sidewalls 632 (see FIG. 10) of gap fill layer 630A that define a via 670 (see FIG. 10) during fabrication. The top barrier layer 650, acting as an upper metal electrode in the MIM structure, may comprise, for instance, 20-3000 angstroms of TiN or another similar conductive adhesion or barrier material.

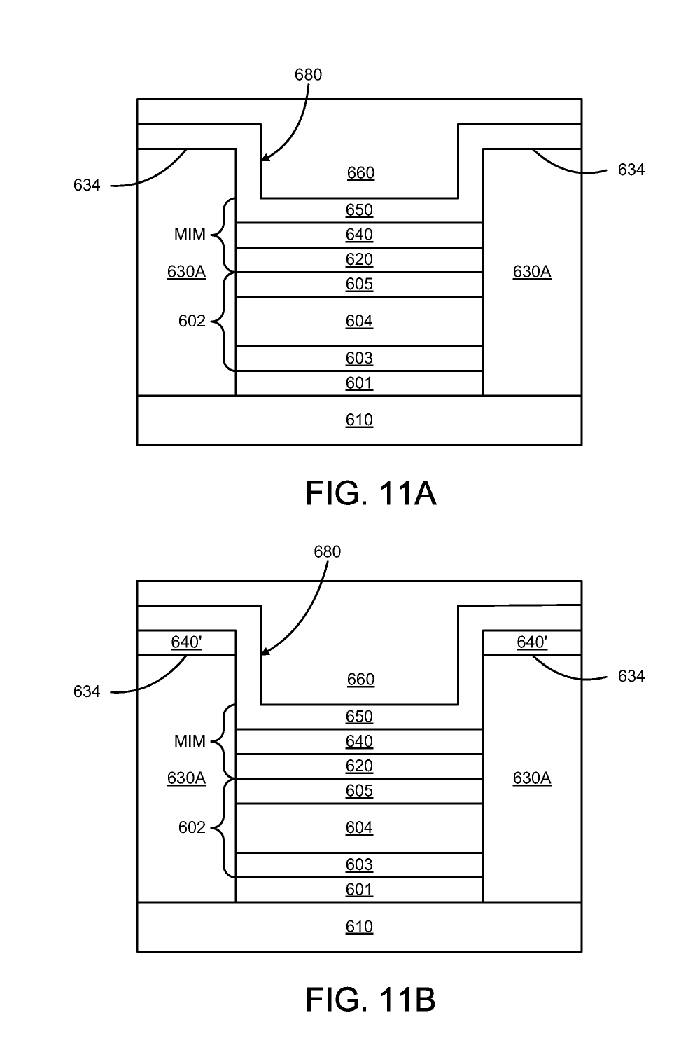

Above the top barrier layer 650, and within a cavity 680 (see FIG. 11A) defined during fabrication by vertical portions of the top barrier layer 650, is a top conductor 660 that fills in via 670 defined by the sidewalls 632 of the gap fill layer 630A. The top conductor 660 may comprise, for instance, 500-3000 angstroms of W, or another similar conductive material. The top barrier layer 650 is a conductive layer in ohmic contact with the top conductor 660, which also is a conductive layer. Alternatively, top barrier layer 650 may be omitted (not shown), such that the top conductor 660 is formed directly on the nonconformal carbon-based resistivity-switchable material layer 640.

Thus, as depicted in FIGS. 6A and 6B, microelectronic structures 600A and 600B each include a first conductive layer (e.g., bottom conductor 610 and/or adhesion layer 601), a via 670 formed above the first conductive layer, a nonconformal carbon-based resistivity-switchable material layer 640 disposed in the via 170 and coupled to the first conductive layer, and a second conductive layer (e.g., top barrier layer 650 and/or the top conductor 660) in the via 670, above and coupled to the nonconformal carbon-based resistivity-switchable material layer 640.

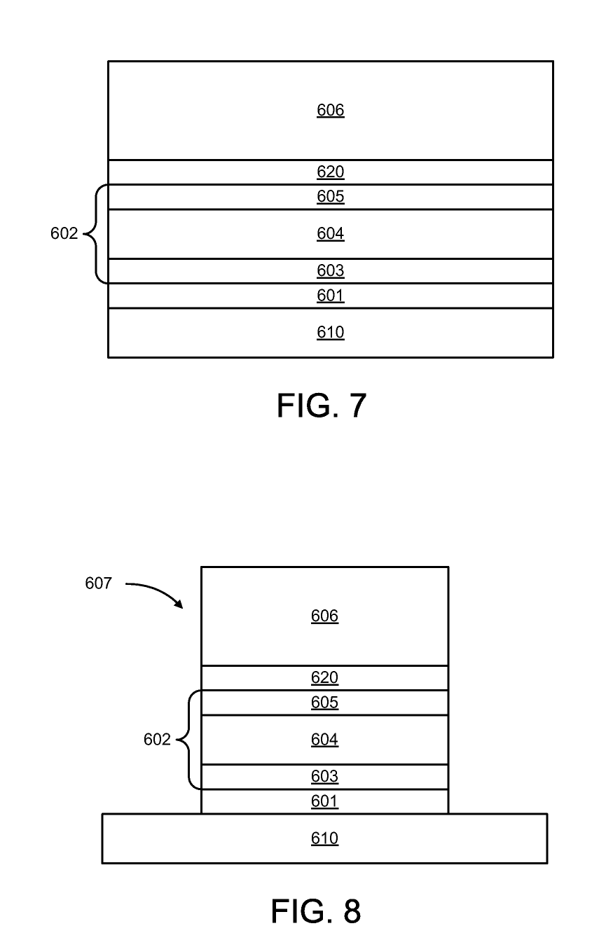

Referring to FIGS. 7 to 12B, cross-sectional, side elevational views of intermediate stages of device fabrication depict highlights of an exemplary method embodiment of the current invention to create microelectronic structures 600A, 600B. Intermediate products of some, but not all process steps are depicted, and the progression of one intermediate product to the next is explained in the following text, taking into account the ordinary level of skill in the semiconductor manufacturing arts.

As shown in FIG. 7, formation of microelectronic structures 600A, 600B begins with formation of the bottom conductor 610, followed by deposition of adhesion material for adhesion layer 601. On top of the adhesion layer 601, the layers of material for the p-i-n diode 602 are deposited. First, heavily doped n+ semiconductor material is deposited on adhesion layer 601 for n+ layer 603, followed by deposition of intrinsic material for i layer 604, which is followed by deposition of heavily doped p+ semiconductor material for p+ layer 605. On top of p+ layer 605 is then deposited barrier material for the first, bottom barrier layer 620. A sacrificial layer 606 of semiconductor material, such as Ge or other similar sacrificial material, may be deposited on top of barrier layer 620, for eventual formation (see FIG. 10) of the via 670 after the diode 602 has been etched into a pillar and surrounded by gap fill material 630A.

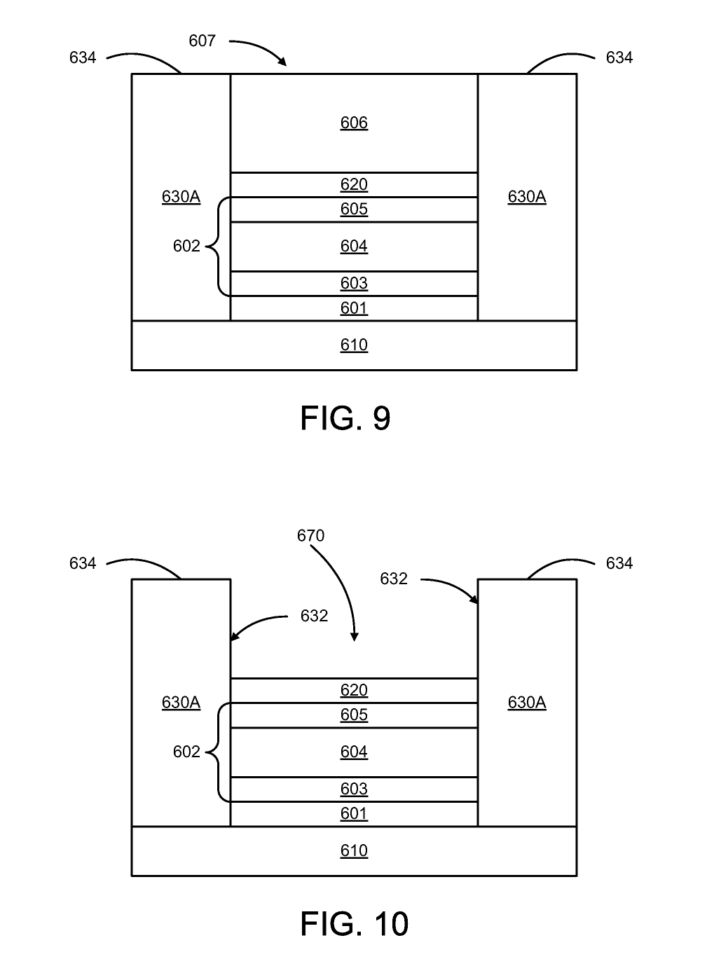

As shown in FIGS. 8 and 9, a single photolithography patterning step may be used to pattern the diode 602. FIG. 8 depicts the diode 602, bottom barrier layer 620, and sacrificial layer 606 after they have been etched to form a pillar 607 in a single patterning step. FIG. 9 depicts the pillar 607 after gap fill material has been deposited to form gap fill layer 630A. Planarization such as by CMP or dielectric etch back may be performed to achieve a planar surface, as shown in FIG. 9, between the sacrificial layer 606 and a top surface 634 of the gap fill layer 630.

As shown in FIG. 10, the sacrificial layer 606 then may be etched to form via 670, selectively etching the sacrificial semiconductor material to stop the etch upon reaching the bottom barrier layer 620. Bottom barrier layer 620 then may be used to form a basis of the MIM feature.

As shown in FIG. 11A, nonconformal carbon-based resistivity-switchable material layer 640, such as amorphous carbon or other similar resistivity-switchable material, may be formed on the bottom barrier layer 620. In the embodiment of FIG. 11A, a carbon layer has been deposited selectively onto the metal layer 620 using selective deposition techniques set forth in the '111 application.

Use of selective deposition may involve omission of the bottom barrier layer 620, so that the nonconformal carbon-based resistivity-switchable material layer 640 is deposited directly on a tungsten first conductor 610. Selective deposition of the nonconformal carbon-based resistivity-switchable material layer 640 is followed by deposition of metal barrier material, for the top barrier layer 650, in the via 670, with some metal barrier material being deposited above the gap fill material 630, and up along the sidewalls 632 of gap fill layer 630A, forming a cavity 680 lined with barrier material within via 670. Above the barrier material for the top barrier layer 650, and into cavity 680, a layer of conductive material is formed, out of which the top conductor 660 is formed. The top barrier layer 650, and/or the top conductor 660 may form a second conductive layer above the nonconformal carbon-based resistivity-switchable material layer 640.

In another exemplary embodiment, as shown in FIG. 11B, nonconformal carbon-based resistivity-switchable material layer 640 may be deposited non-selectively on bottom barrier layer 620 in via 670. For instance, in a PECVD process, increasing an ionic component (e.g., carrier gas species) of a plasma compared to a precursor component (e.g., carbon species) of the plasma may provide a flux of ionic species that carry precursor species to a substrate surface with increased directionality.

Use of high and/or low frequency RF may assist in driving the ionic species (and thus precursor species) to the substrate surface, as may substrate bias. Some nonconformal carbon-based resistivity-switchable material 640′ also will be deposited above the gap fill material 630. Formation of the nonconformal carbon-based resistivity-switchable material layer 640 is followed by deposition of the barrier material for the top barrier layer 650, also in the via 670. Thereafter, the conductive material for the top conductor 660 may be deposited.

During PECVD formation of a carbon-based material, use of an etchant carrier gas, such as H₂ or other similar gas, will reduce the deposition on sidewalls and form nonconformal carbon-based resistivity-switchable material by PECVD. Etchant carrier gases such as H₂ may form radicals, such as H radicals, and ion species during plasma, which etch away the deposition on sidewall.

In some embodiments, the nonconformal carbon-based resistivity-switchable material may be composed of amorphous carbon or a dielectric filler material mixed with graphitic carbon, deposited in any of the above mentioned techniques. Alternative exemplary embodiments include a spin or spray application of the CNT material, followed by deposition of amorphous carbon for use as carbon-based liner material. The optional carbon-based protective liner can be deposited using a deposition technique similar to or different than that used to deposit the CNT material.

In addition to using plasma-based techniques, carbon-based films may be formed using other processes such as low pressure or subatmospheric CVD. For example, similar or the same precursor and/or carrier/dilutant gases described herein may be used to form a carbon-based film using a processing temperature of about 300 to 1000° C., and more preferably about 600-900° C., and a pressure range of about 1 to 150 Torr, and more preferably about 10 to 100 Torr. Other precursors, temperatures and/or pressures may be used.

The nonconformal carbon-based resistivity-switchable material may be deposited in any thickness. In some embodiments, the nonconformal carbon-based resistivity-switchable material may be between about 1-1000 angstroms, although other thicknesses may be used. Depending on device construction, such as described herein, exemplary ranges may include 200-400 angstroms, 400-600 angstroms, 600-800 angstroms, and 800-1000 angstroms.

In yet another embodiment, nonconformal carbon-based resistivity-switchable material layer 640 may be deposited on bottom barrier layer 620 in a shorter version of via 670, with some nonconformal resistivity-switchable material 640′possibly being deposited above the gap fill material 630A, followed by deposition of the barrier material for the top barrier layer 650 also in the shorter version of via 670.

With the barrier material for the top barrier layer 650 in place to cover and protect the nonconformal carbon-based resistivity-switchable material layer 640, an etch back or CMP process may be used to planarize the shorter version of the via 670, making the MIM stack coplanar with the gap fill layer 630A, leaving the nonconformal carbon-based resistivity-switchable material layer 640 covered by the top barrier layer 650. More gap fill dielectric 630A then may be deposited and etched back to the top barrier layer 650 to form an upper portion of via 670, after which the conductive material for the top conductor 660 is deposited.

Deposition of the conductive material for the top conductor 660 may be preceded by deposition of additional barrier material to augment the barrier layer above the nonconformal carbon-based resistivity-switchable material layer 640 as part of the formation of top barrier layer 650.

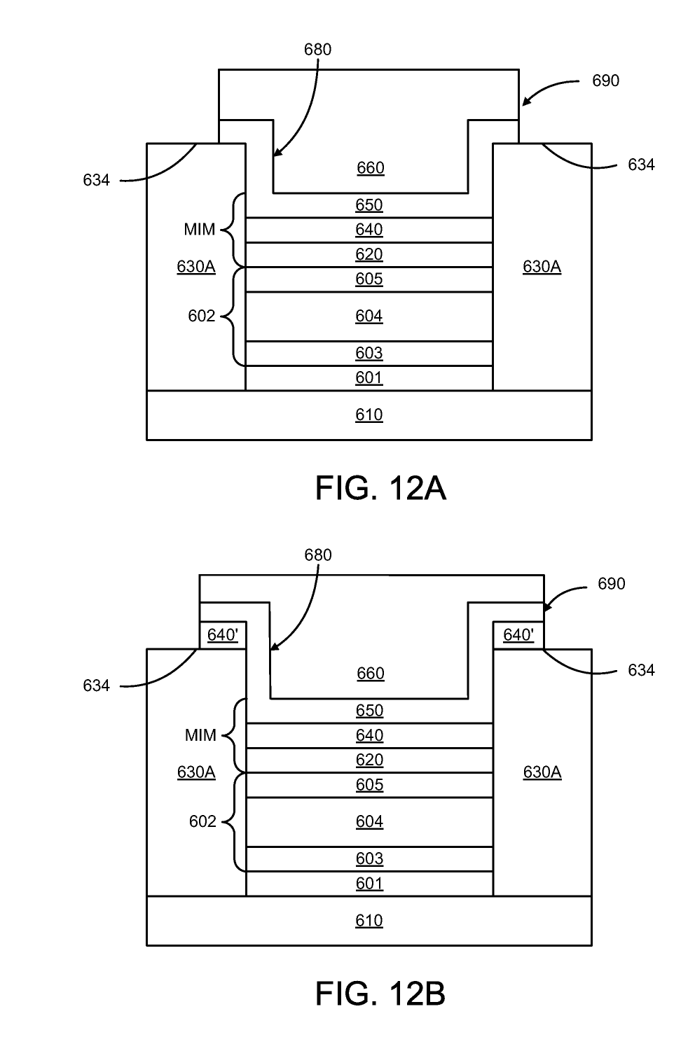

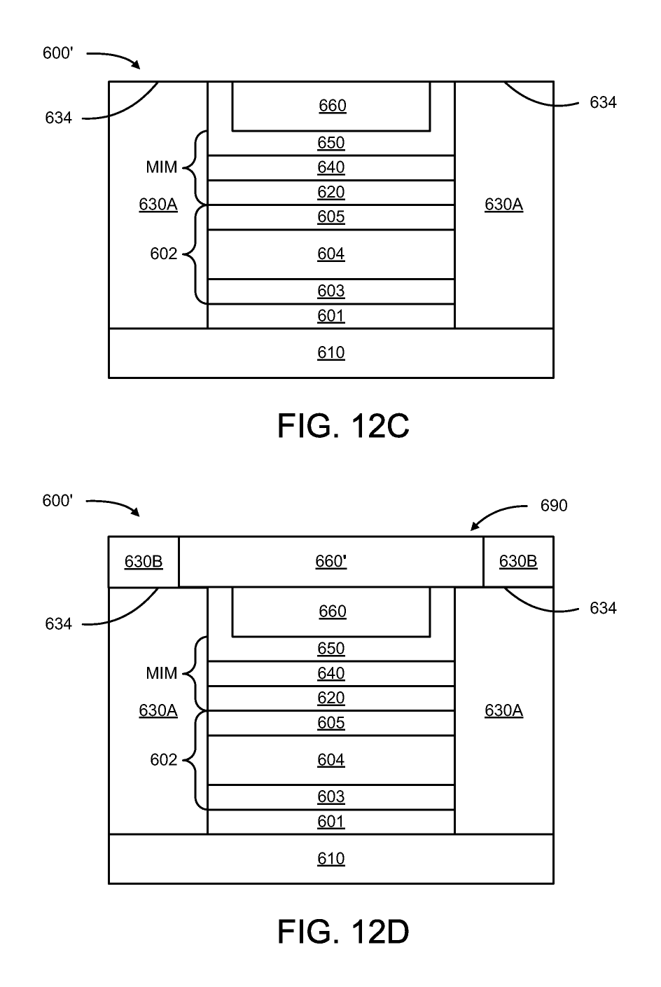

As shown in FIGS. 12A and 12B, the barrier material 650, the conductive material 660, and any nonconformal carbon-based resistivity-switchable material 640′ above the gap fill layer 630A may be patterned and etched back to the gap fill layer 630A, exposing a rail 690 of the top barrier layer 650 and the top conductor 660. Additional gap fill dielectric material, in the form of layer 630B, may then be added to the gap fill layer 630A to at least the height of the top conductor 660, and the gap fill layer 630B may be planarized, such as by CMP, to make the gap fill layer 630B coplanar with a top surface 662 of the top conductor 660.

If the etch back leaves the top conductor 660 with a width wider than the feature width of the diode 602, and nonconformal carbon-based resistivity-switchable material 640′ is selectively non-conformally formed, such that no nonconformal carbon-based resistivity-switchable material 640′ is above the gap fill layer 630, an embodiment 600A as shown in FIGS. 6A and 12A is achieved.

Non-selective formation results in embodiment 600B of FIGS. 6B and 12B. As shown in FIG. 12B, an alternative exemplary embodiment may include some nonconformal carbon-based resistivity-switchable material 640′ above the gap fill layer 630A. The etch back may leave the top conductor 660 with a width wider than the feature width of the diode 602, in which case the etch back will leave some of the nonconformal carbon-based resistivity-switchable material 640′ above the gap fill layer 630A, which will be enclosed by layer 630B when the additional gap fill material is added to the gap fill layer 630A.

Alternatively, as shown in FIG. 12C, the barrier material and the conductive material above the gap fill layer 630A may be planarized, such as by CMP, to be made coplanar with a top surface 634 of the gap fill layer 630A. In the event that the top barrier layer 650 extends vertically up the sidewalls of the gap fill layer 630A to the level of the top surface of the gap fill layer 630A, then such planarization will co-expose the top barrier layer 650 and the top conductor 660 along with the gap fill layer 630A.

The alternative result is depicted as integration scheme 600′ in FIG. 12C, which is ready for further processing and may require additional conductive material 660′, above gap fill layer 630A, to complete electrical connection of the top conductor 660 between feature rails 690, as shown in FIG. 12D.

Analogous to embodiment 600′ shown in FIG. 12C, other embodiments may involve an etch back leaving the top conductor 660 with a width the same as the feature width of the diode 602, in which case the etch back will leave none of the barrier material, the conductive material, or the nonconformal carbon-based resistivity-switchable material 640′ above the gap fill layer 630A, irrespective of whether nonconformal carbon-based resistivity-switchable material 640′ is above the gap fill layer 630A before the rail 690 is enclosed by layer 630B when the additional gap fill material that is added to the gap fill layer 630A.

MIM with a Damascene-Formed Diode

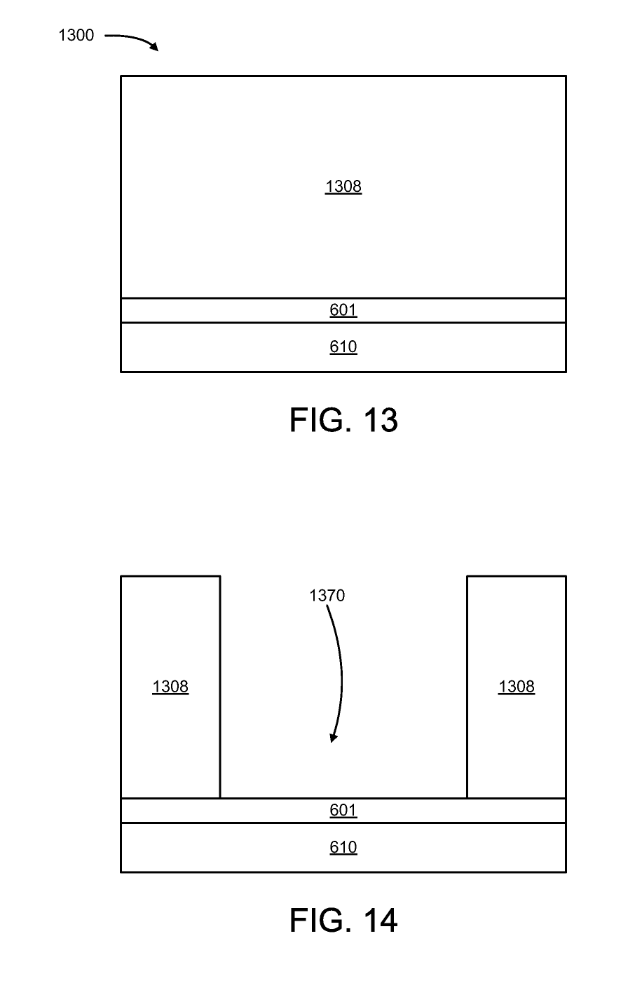

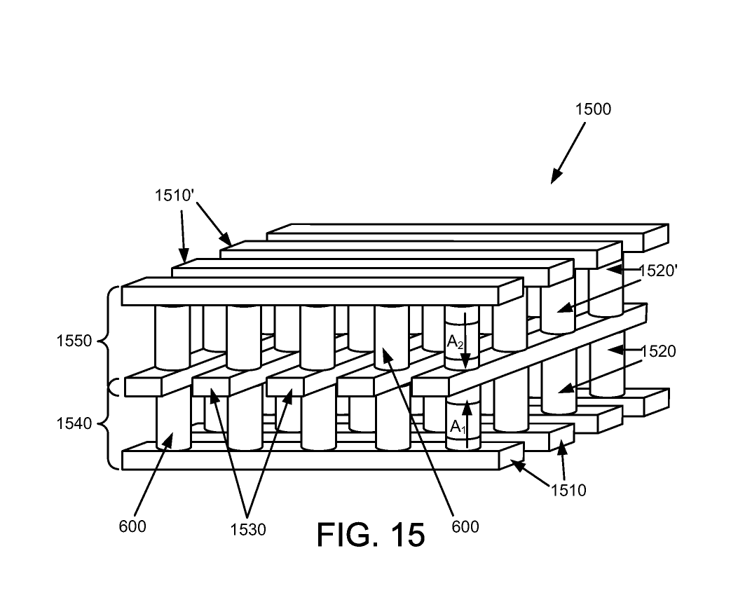

As an alternative to the etch-patterning formation of diode 602 described above in reference to FIGS. 7-9, the diode 602 may be formed using a damascene method. Preferably, the PIN diode 602 is selectively grown within a damascene via. Once the diode 602 is formed, the MIM structure may then be formed atop the diode 602 in a continuation of the damascene sequence. Thus, a process beginning with FIGS. 13 and 14 will continue by proceeding with the steps described in reference with FIGS. 10 to 12D, as described above.

Referring to FIGS. 13 and 14, cross-sectional, side elevational views of a memory cell depict a further exemplary integration scheme 1300 in accordance with the present invention. Integration scheme 1300 involves an MIM structure with a steering element, e.g., a diode, both of which are formed using a damascene method.

As shown in FIG. 13, integration scheme 1300 may begin with a first, bottom conductor 610, on which is deposited an adhesion layer 601, which also may serve as a barrier layer and may be comprised of barrier material. On top of the adhesion layer 601, a sacrificial dielectric layer 1308 is formed, which may comprise SiO₂, for example.

As shown in FIG. 14, the sacrificial dielectric layer 1308 may be etched to form a via 1370. The etch may be selective to the dielectric material, to stop the etch upon reaching the adhesion layer 601. Within the via 1370, the diode 602 may be formed on top of adhesion layer 601, and the first, bottom barrier layer 620 may be formed over the diode 602, as shown in FIG. 10. If any material should be removed from above the dielectric layer 1308 after deposition of the diode 602 and bottom barrier layer 620, a subsequent planarization step may be performed. At this point, the process continues as described above in reference to FIGS. 11 to 12. As FIGS. 2, 8, and 14 show, only one photolithographic patterning step is needed for the MIM structure, with or without a steering element.

Monolithic Three Dimensional Memory Array

In accordance with a further exemplary embodiment of this invention, formation of a microelectronic structure includes formation of a monolithic three dimensional memory array including memory cells, each memory cell comprising an MIM device formed by damascene integration, the MIM having a carbon-based memory element disposed between a bottom electrode and a top electrode and covered by a conductive layer, as described above. The carbon-based memory element may comprise a nonconformal amorphous-carbon-based resistivity-switchable material layer. The top electrode in the MIM optionally may be deposited using a conformal deposition technique.

FIG. 15 shows a portion of a memory array 1500 of exemplary memory cells formed according to the third exemplary embodiment of the present invention. A first memory level is formed above the substrate, and additional memory levels may be formed above it. Details regarding memory array formation are described in the applications incorporated by reference herein, and such arrays may benefit from use of the methods and structures according to embodiments of the present invention.

As shown in FIG. 15, memory array 1500 may include first conductors 1510 and 1510′ that may serve as wordlines or bitlines, respectively; pillars 1520 and 1520′ (each pillar 1520, 1520′ comprising a memory cell); and second conductors 1530, that may serve as bitlines or wordlines, respectively. First conductors 1510, 1510′ are depicted as substantially perpendicular to second conductors 1530. Memory array 1500 may include one or more memory levels. A first memory level 1540 may include the combination of first conductors 1510, pillars 1520 and second conductors 1530, whereas a second memory level 1550 may include second conductors 1530, pillars 1520′ and first conductors 1510′. Fabrication of such a memory level is described in detail in the applications incorporated by reference herein.

Embodiments of the present invention are useful in formation of a monolithic three dimensional memory array. A monolithic three dimensional memory array is one in which multiple memory levels are formed above a single substrate, such as a wafer, with no intervening substrates. The layers forming one memory level are deposited or grown directly over the layers of an existing level or levels. In contrast, stacked memories have been constructed by forming memory levels on separate substrates and adhering the memory levels atop each other, as in Leedy, U.S. Pat. No. 5,915,167. The substrates may be thinned or removed from the memory levels before bonding, but as the memory levels are initially formed over separate substrates, such memories are not true monolithic three dimensional memory arrays.

A related memory is described in Herner et al., U.S. patent application Ser. No. 10/955,549, “Nonvolatile Memory Cell Without A Dielectric Antifuse Having High- And Low-Impedance States,” filed Sep. 29, 2004 (hereinafter the '549 application), which is hereby incorporated by reference herein in its entirety for all purposes. The '549 application describes a monolithic three dimensional memory array including vertically oriented p-i-n diodes like diode 602 of FIG. 6. As formed, the polysilicon of the p-i-n diode of the '549 application is in a high-resistance state. Application of a programming voltage permanently changes the nature of the polysilicon, rendering it low-resistance. It is believed the change is caused by an increase in the degree of order in the polysilicon, as described more fully in Herner et al., U.S. patent application Ser. No. 11/148,530, “Nonvolatile Memory Cell Operating By Increasing Order In Polycrystalline Semiconductor Material,” filed Jun. 8, 2005 (the “'530 application”), which is incorporated by reference herein in its entirety for all purposes.

Another related memory is described in Herner et al., U.S. Pat. No. 7,285,464, (the “'464 patent”), which is incorporated by reference herein in its entirety. As described in the '464 patent, it may be advantageous to reduce the height of the p-i-n diode. A shorter diode requires a lower programming voltage and decreases the aspect ratio of the gaps between adjacent diodes. Very high-aspect ratio gaps are difficult to fill without voids. A thickness of at least 600 angstroms is exemplary for the intrinsic region to reduce current leakage in reverse bias of the diode. Forming a diode having a silicon-poor intrinsic layer above a heavily n-doped layer, the two separated by a thin intrinsic capping layer of silicon-germanium, will allow for sharper transitions in the dopant profile, and thus reduce overall diode height.

In particular, detailed information regarding fabrication of a similar memory level is provided in the '549 application and the '464 patent, previously incorporated. More information on fabrication of related memories is provided in Herner et al., U.S. Pat. No. 6,952,030, “A High-Density Three-Dimensional Memory Cell,” owned by the assignee of the present invention and hereby incorporated by reference herein in its entirety for all purposes. To avoid obscuring the present invention, this detail will be not be reiterated in this description, but no teaching of these or other incorporated patents or applications is intended to be excluded. It will be understood that the above examples are non-limiting, and that the details provided herein can be modified, omitted, or augmented while the results fall within the scope of the invention.

In exemplary embodiments of this invention described above, the order of the layers may be modified, and thus, the phrase “deposited on,” and the like, in the description and the claims includes a layer deposited above the prior layer, but not necessarily immediately adjacent the prior layer, as it can be higher in the stack.

The foregoing description discloses exemplary embodiments of the invention. Modifications of the above disclosed apparatus and methods that fall within the scope of the invention will be readily apparent to those of ordinary skill in the art. Accordingly, although the present invention has been disclosed in connection with exemplary embodiments, it should be understood that other embodiments may fall within the spirit and scope of the invention, as defined by the following claims.

1. A method for forming a microelectronic structure, the method comprising:
forming a via above a first conductive layer;
forming a nonconformal carbon-based resistivity-switchable material layer in the via and coupled to the first conductive layer; and
forming a second conductive layer in the via, above and coupled to the nonconformal carbon-based resistivity-switchable material layer.

2. The method of claim 1, wherein the second conductive layer is disposed on the nonconformal carbon-based resistivity-switchable material layer.

3. The method of claim 1, wherein the nonconformal carbon-based resistivity-switchable material layer has a thickness of between about 50 angstroms and about 1000 angstroms.

4. The method of claim 1, wherein the nonconformal carbon-based resistivity-switchable material layer comprises amorphous carbon.

5. The method of claim 1, wherein the nonconformal carbon-based resistivity-switchable material layer comprises microcrystalline or nanocrystalline graphitic carbon.

6. The method of claim 1, wherein the nonconformal carbon-based resistivity-switchable material layer comprises amorphous diamond-like carbon.

7. The method of claim 1, wherein the nonconformal carbon-based resistivity-switchable material layer is formed using one or more hydrocarbon compounds comprising CₓH_{y}, wherein x has a range of 2 to 4 and y has a range of 2 to 10.

8. The method of claim 1, wherein the nonconformal carbon-based resistivity-switchable material layer is formed using a processing gas comprising hydrogen and at least one precursor compound having a formula of CₐH_{b}O_{c}NₓF_{y}, wherein “a” has a range of between 1 and 24, “b” has a range of between 0 and 50, “c” has a range of 0 to 10, “x” has a range of 0 to 50, and “y” has a range of 1 to 50.

9. The method of claim 1, wherein the one or more hydrocarbon compounds comprise one or more of propylene (C₃H₆), propyne (C₃H₄), propane (C₃H₈), butane (C₄H₁₀), butylene (C₄H₈), butadiene (C₄H₆), acetelyne (C₂H₂), and combinations thereof.

10. The method of claim 1, wherein the nonconformal carbon-based resistivity-switchable material layer is formed using a carrier gas comprising at least one of He, Ar, Kr, Xe, H₂ and N₂.

11. The method of claim 1, wherein forming the nonconformal carbon-based resistivity-switchable material layer comprises using nonconformal plasma enhanced chemical vapor deposition.

12. The method of claim 11, wherein using nonconformal plasma enhanced chemical vapor deposition comprises applying a first RF power at a first frequency and applying a second RF power at a second frequency less than the first frequency.

13. The method of claim 12, wherein the first frequency is between about 10 Mhz and about 50 Mhz and the second frequency is between about 90 kHz and about 500 KHz.

14. The method of claim 12, wherein the ratio of the second RF power to the first RF power is between about 0:1 and about 1:1.

15. The method of claim 12, wherein the first RF power ranges from about 30 W to about 1000 W, and the second RF power ranges from about 0 W to about 500 W.

16. The method of claim 15, wherein an RF power density of the plasma ranges from about 0.1 Watt/in² to about 20 Watts/in².

17. The method of claim 1, wherein the nonconformal carbon-based resistivity-switchable material layer is formed using a ratio of carrier gas to hydrocarbon compounds ranging from about 1:1 to 100:1.

18. The method of claim 1, wherein the nonconformal carbon-based resistivity-switchable material layer is formed using a pressure within a processing chamber ranging from about 0.2 Torr to about 10 Torr.

19. The method of claim 1, wherein the nonconformal carbon-based resistivity-switchable material layer is formed using a hydrocarbon gas flow rate ranging from about 50 to about 5000 sccm.

20. The method of claim 1, wherein the nonconformal carbon-based resistivity-switchable material layer is formed using a carrier gas flow rate ranging from about 50 sccm to about 20,000 sccm.

21. The method of claim 1, wherein forming the nonconformal carbon-based resistivity-switchable material layer comprises selective deposition of a carbon-based resistivity-switchable material.

22. The method of claim 1, wherein forming the nonconformal carbon-based resistivity-switchable material layer comprises PVD sputtering of carbon-based target material.

23. The method of claim 1, wherein forming the second conductive layer comprises forming a conformal layer of conductive material on the nonconformal carbon-based resistivity-switchable material layer.

24. The method of claim 23, further comprising:
forming a bottom electrode below and in contact with the nonconformal carbon-based resistivity-switchable material layer;
wherein the second conductive layer comprises a top electrode of an MIM structure, the MIM structure further comprising the bottom electrode and the nonconformal carbon-based resistivity-switchable material layer.

25. The method of claim 1, further comprising:
forming a steering element coupled to the nonconformal carbon-based resistivity-switchable material layer.

26. The method of claim 25, wherein the steering element comprises a diode substantially vertically aligned with the nonconformal carbon-based resistivity-switchable material layer.

27. The method of claim 25, wherein forming the steering element comprises using selective formation of semiconductor material.

28. The method of claim 1, further comprising:
forming a first conductor below the first conductive layer; and
forming a second conductor above the second conductive layer;
wherein the microelectronic structure comprises a memory cell.

29. The method of claim 1, wherein the second conductive layer has a thickness of between about 50 angstroms and about 300 angstroms.

30. A memory device formed according to the method of claim 1.

31. A microelectronic structure comprising:
a via formed above a first conductive layer;
a nonconformal carbon-based resistivity-switchable material layer disposed in the via and coupled to the first conductive layer; and
a second conductive layer in the via, above and coupled to the nonconformal carbon-based resistivity-switchable material layer.

32. The microelectronic structure of claim 31, wherein the nonconformal carbon-based resistivity-switchable material layer has a thickness of between about 50 angstroms and about 1000 angstroms.

33. The microelectronic structure of claim 31, wherein the nonconformal carbon-based resistivity-switchable material layer comprises amorphous carbon.

34. The microelectronic structure of claim 31, wherein the nonconformal carbon-based resistivity-switchable material layer comprises microcrystalline or nanocrystalline graphitic carbon.

35. The microelectronic structure of claim 31, wherein the nonconformal carbon-based resistivity-switchable material layer comprises amorphous diamond-like carbon.

36. The microelectronic structure of claim 31, wherein the second conductive layer is disposed on and in contact with the nonconformal carbon-based resistivity-switchable material layer.

37. The microelectronic structure of claim 36, wherein the second conductive layer comprises a conformal layer of conductive metal barrier and adhesion material.

38. The microelectronic structure of claim 37, wherein the second conductive layer has a thickness of between about 50 angstroms and about 300 angstroms.

39. The microelectronic structure of claim 37, further comprising:
a bottom electrode disposed below and in contact with the nonconformal carbon-based resistivity-switchable material layer;
wherein the conformal layer of conductive metal barrier and adhesion material comprises a top electrode of an MIM structure, the MIM structure further including the bottom electrode and the nonconformal carbon-based resistivity-switchable material layer.

40. The microelectronic structure of claim 31, wherein the nonconformal carbon-based resistivity-switchable material layer is selectively disposed in the via and not on the layer of dielectric material.

41. The microelectronic structure of claim 31, further comprising a steering element disposed in the via and coupled to the nonconformal carbon-based resistivity-switchable material layer.

42. The microelectronic structure of claim 41, wherein the steering element comprises a diode substantially vertically aligned with the nonconformal carbon-based resistivity-switchable material layer.

43. The microelectronic structure of claim 31, further comprising:
a first conductor below the first conductive layer; and
a second conductor disposed above the second conductive layer;
wherein the nonconformal carbon-based resistivity-switchable material layer, the first conductive layer, and the second conductive layer comprise a memory cell disposed between the first conductor and the second conductor.

44. A memory device comprising:
a steering element; and
a memory element coupled to the steering element;
wherein the memory element comprises:
a nonconformal carbon-based resistivity-switchable material layer disposed in a via above a first conductive layer.

45. The memory device of claim 44, wherein the nonconformal carbon-based resistivity-switchable material layer is coupled to the first conductive layer and a second conductive layer.

46. The memory device of claim 45, further comprising:
the first conductive layer and the second conductive layer,
wherein the first conductive layer is disposed below the nonconformal carbon-based resistivity-switchable;
wherein the second conductive layer is disposed in the via and above the nonconformal carbon-based resistivity-switchable material layer; and
wherein the first conductive layer, the nonconformal carbon-based resistivity-switchable material layer, and the second conductive layer comprise a MIM stack.

47. The memory device of claim 46, wherein the second conductive layer comprises a conformal layer of conductive metal barrier and adhesion material.

48. The memory device of claim 47, wherein the second conductive layer has a thickness of between about 50 angstroms and about 300 angstroms.

49. The memory device of claim 46, further comprising:
a first conductor below the first conductive layer; and
a second conductor disposed above the second conductive layer;

50. The memory device of claim 49, wherein the steering element comprises a diode disposed in the via and substantially vertically aligned with the nonconformal carbon-based resistivity-switchable material layer.

51. The memory device of claim 50, wherein the first conductive layer, the nonconformal carbon-based resistivity-switchable material layer, the diode, and the second conductive layer comprise a memory cell disposed between the first conductor and the second conductor.

52. The memory device of claim 44, wherein the steering element comprises a transistor.

53. The memory device of claim 44, wherein the nonconformal carbon-based resistivity-switchable material layer has a thickness of between about 50 angstroms and about 1000 angstroms.

54. The memory device of claim 44, wherein the nonconformal carbon-based resistivity-switchable material layer comprises amorphous carbon.

55. The memory device of claim 44, wherein the nonconformal carbon-based resistivity-switchable material layer comprises microcrystalline or nanocrystalline graphitic carbon.

56. The memory device of claim 44, wherein the nonconformal carbon-based resistivity-switchable material layer comprises amorphous diamond-like carbon.
